(19) United States
(12) Patent Application Publication
(10) Pub. No.: US 2016/0033802 A1
(43) Pub. Date: Feb. 4, 2016

(54) DISPLAY PANEL AND DISPLAY DEVICE

(71) Applicant: INNOLUX CORPORATION, Jhu-Nan (TW)

(72) Inventors: Shu-Bai LIU, Jhu-Nan (TW); Shie-Ping CHANG, Jhu-Nan (TW); Ying-Chieh TSAI, Jhu-Nan (TW); Yi-Ching CHEN, Jhu-Nan (TW); Chao-Hsiang WANG, Jhu-Nan (TW)

(21) Appl. No.: 14/517,304

(22) Filed: Oct. 17, 2014

(30) Foreign Application Priority Data
Jul. 30, 2014 (TW) 103126098

(51) Int. Cl. G02F 1/133; G02F 1/1368; G02F 1/1343; H01L 27/12

(52) U.S. Cl. CPC G02F 1/13306; H01L 27/124; G02F 1/1368; G02F 1/134363; G02F 2001/134372

(57) ABSTRACT

The present invention discloses a display panel and a display device. The display panel includes a first substrate, a second substrate disposed opposite the first substrate, and a pixel array. The pixel array is disposed on the first substrate and at least includes a pixel. The pixel has a first electrode layer. The first electrode layer has an auxiliary electrode portion and a driving electrode portion connecting to the auxiliary electrode portion. The driving electrode portion has a plurality of strip electrodes spaced from each other and arranged along a first direction. The area of the auxiliary electrode portion is denoted by A1. The pixel has a light-emitting zone when a light passes through the pixel. The area of the light-emitting zone is denoted by B. A1 and B satisfy the following equation: 0.11×B≦A1≦0.27×B, and the units of A1 and B are the same.

### CROSS REFERENCE TO RELATED APPLICATIONS

This Non-provisional application claims priority under 35 U.S.C. §119(a) on Patent Application No(s). 103126098 filed in Taiwan, Republic of China on Jul. 30, 2014, the entire contents of which are hereby incorporated by reference.

### BACKGROUND OF THE INVENTION

1. Field of Invention

The invention relates to a display panel and a display device and, in particular, to a display panel and display device having higher transmittance.

2. Related Art

With the progress of technologies, flat display devices have been widely applied to various kinds of fields. Especially, liquid crystal display (LCD) devices, having advantages such as compact structure, low power consumption, less weight and less radiation, gradually take the place of cathode ray tube (CRT) display devices, and are widely applied to various electronic products, such as mobile phones, portable multimedia devices, notebooks, LCD TVs and LCD screens.

A conventional LCD apparatus mainly includes an LCD panel and a backlight module disposed opposite to the LCD panel. The LCD panel mainly includes a thin film transistor (TFT) substrate, a color filter (CF) substrate and a liquid crystal layer disposed between the two substrates. The CF substrate, the TFT substrate and the LC layer can form a plurality of pixel units disposed in an array. The backlight module can emit the light passing through the LCD panel, and the pixel units of the LCD panel can display colors forming images accordingly.

For the same luminance, a display panel with a higher transmittance can save more energy for the display device. Therefore, the industry strives to increase the transmittance of the display panel to save more energy and enhance the product competitiveness.

### SUMMARY OF THE INVENTION

An objective of the invention is to provide a display panel and a display device which can have higher transmittance so as to enhance the product competitiveness.

To achieve the above objective, a display panel according to the invention includes a first substrate, a second substrate and a pixel array. The second substrate is disposed opposite the first substrate. The pixel array is disposed on the first substrate and at least includes a pixel including a first electrode layer. The first electrode layer has an auxiliary electrode portion and a driving electrode portion connecting to the auxiliary electrode portion. The driving electrode portion has a plurality of strip electrodes spaced from each other and arranged along a first direction. The area of the auxiliary electrode portion is denoted by A1, when a light passes through the pixel, the pixel has a light-emitting zone having an area denoted by B. A1 and B satisfy the following equation: 0.11×B≦A1≦0.27×B, and the units of A1 and B are the same.

To achieve the above objective, a display device according to the invention includes a display panel. The display panel includes a first substrate, a second substrate and a pixel array. The second substrate is disposed opposite the first substrate. The pixel array is disposed on the first substrate and at least includes a pixel including a first electrode layer. The first electrode layer has an auxiliary electrode portion and a driving electrode portion connecting to the auxiliary electrode portion. The driving electrode portion has a plurality of strip electrodes spaced from each other and arranged along a first direction. The area of the auxiliary electrode portion is denoted by A1, when a light passes through the pixel, the pixel has a light-emitting zone having an area denoted by B. A1 and B satisfy the following equation: 0.11×B≦A1≦0.27×B, and the units of A1 and B are the same.

In one embodiment, A1 and B further satisfy the following inequality: 0.13×B≦A1≦0.25×B.

In one embodiment, the light-emitting zone has a first brightness curve along the first direction, and has a second brightness curve along the second direction. The area B of the light-emitting zone is the full width at half maximum (FWHM) of the first brightness curve along the first direction multiplied by the FWHM of the second brightness curve along the second direction, and the first direction is perpendicular to the second direction.

In one embodiment, the auxiliary electrode portion has at least a through hole, and the first electrode layer is electrically connected to a thin film transistor by the through hole.

In one embodiment, the driving electrode portion further includes a connecting electrode, which is disposed away from the auxiliary electrode portion and connected to the strip electrodes.

As mentioned above, in the display panel and display device of the invention, the driving electrode portion of the first electrode layer of the pixel has a plurality of strip electrodes spaced from each other along a first direction, and the area of the auxiliary electrode portion is denoted by A1. When a light passes through the pixel, the area of the light-emitting zone of the pixel is denoted by B. A1 and B satisfy the following equation: 0.11×B≦A1≦0.27×B. Thereby, when the area A1 of the auxiliary electrode portion and the area B of the light-emitting zone of the pixel satisfy the above equation, the display panel and device can meet the requirements of both the electric property and the optics, so that the transmittance of the pixel is maximized. Therefore, the display panel and device of the invention can have a higher transmittance and the product competitiveness can be enhanced.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic sectional diagram of a display panel of an embodiment of the invention;

FIG. 1B is a schematic diagram of the first electrode layer of the display panel in FIG. 1A;

FIG. 1C is a schematic diagram of the light-emitting zone of the pixel when a light passes through the pixel in an embodiment of the invention;

FIGS. 1D and 1E are schematic diagrams of brightness distribution curves of the light-emitting zone of the pixel along the first direction and along the second direction, respectively;

FIG. 2 is a schematic diagram showing the relation between the sum of the charging error and the capacitive coupling voltage and the ratio of the area of the auxiliary electrode portion to the area of the light-emitting zone;

FIGS. 3A to 3D are schematic diagrams of the first electrode layers of different embodiments of the invention; and

FIG. 4 is a schematic diagram of a display device of an embodiment of the invention.

### DETAILED DESCRIPTION OF THE INVENTION

The present invention will be apparent from the following detailed description, which proceeds with reference to the accompanying drawings, wherein the same references relate to the same elements.

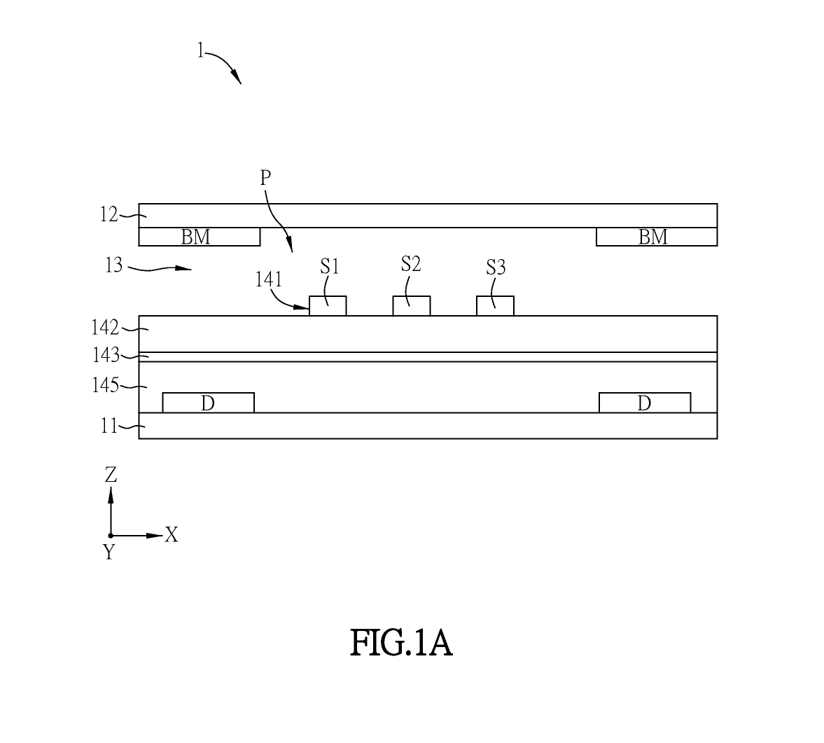

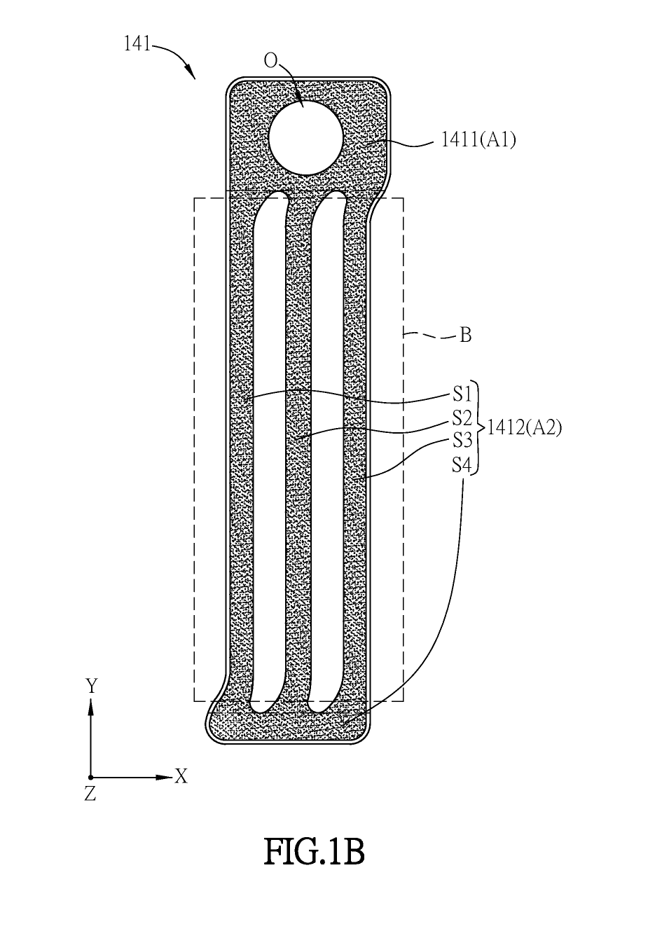

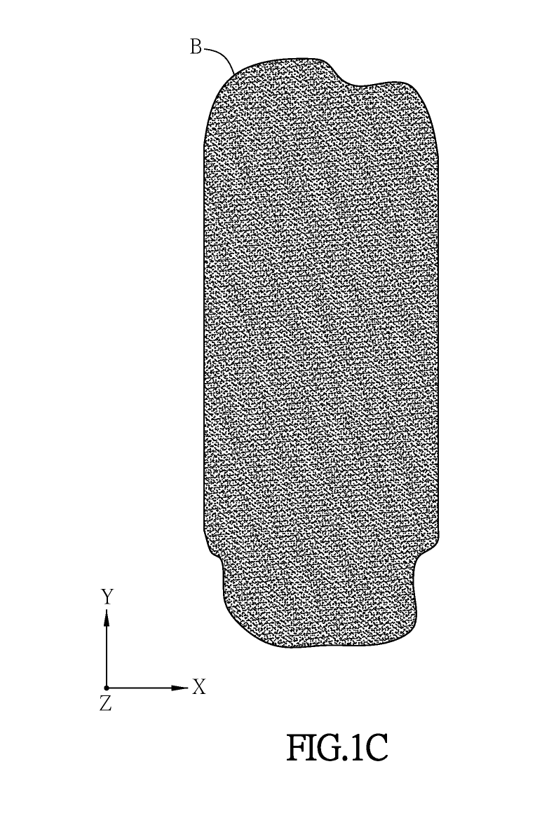

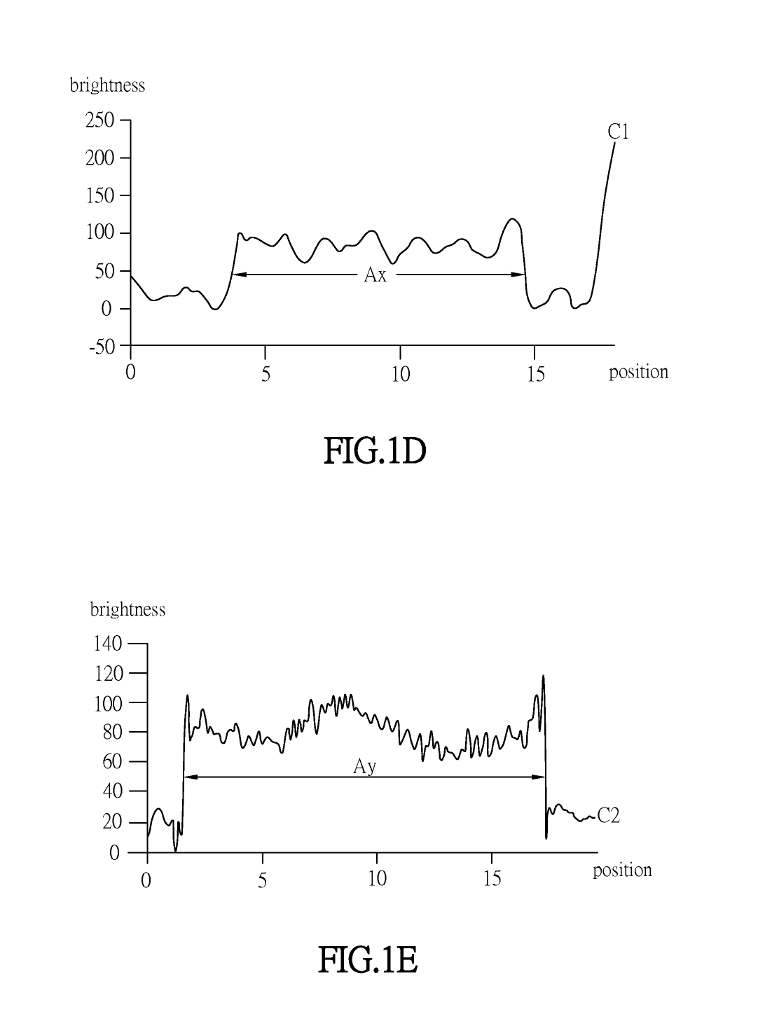

FIG. 1A is a schematic sectional diagram of a display panel 1 of an embodiment of the invention, and FIG. 1B is a schematic diagram of the first electrode layer 141 of the display panel 1 in FIG. 1A. The display panel 1 of this embodiment is, for example but not limited to, a fringe field switching (FFS) LCD panel or other kinds of horizontal driving LCD panels. In this embodiment, a first direction X (horizontal direction), a second direction Y (perpendicular direction) and a third direction Z are shown in FIGS. 1A and 1B, and any two of them are perpendicular to each other. The first direction X can be substantially parallel to the extension direction of the scan line, the second direction Y can be substantially parallel to the extension direction of the data line, and the third direction Z is perpendicular to the first and second directions X and Y.

The display panel 1 includes a first substrate 11, a second substrate 12 and a liquid crystal layer 13. The first substrate 11 and the second substrate 12 are disposed oppositely and the liquid crystal layer 13 is disposed between the first substrate 11 and the second substrate 12. The first substrate 11 and the second substrate 12 are made by transparent material, for example but not limited to a glass substrate, a quartz substrate or a plastic substrate. The display panel 1 further includes a pixel array disposed on the first substrate 11. The pixel array includes at least a pixel (or called a sub-pixel) P, and there are a plurality of pixels P in the display panel 1 of this embodiment. The pixels P are disposed between the first substrate 11 and the second substrate 12 and arranged in a matrix. Moreover, the display panel 1 of this embodiment can further include a plurality of scan lines (not shown) and a plurality of data lines D. The scan lines and the data lines D cross each other and are perpendicular to each other to form the region of the pixel array.

The pixel P includes a first electrode layer 141, an insulating layer 142 and a second electrode layer 143. In this embodiment, the second electrode layer 143, the insulating layer 142 and the first electrode layer 141 are sequentially disposed on the side of the first substrate 11. The data line D is disposed on the first substrate 11. The pixel P can further include another insulating layer 145 covering the data line D, and the second electrode layer 143 is disposed on the another insulating layer 145. The insulating layer 142 covers the second electrode layer 143 and the first electrode layer 141 is disposed on the insulating layer 142. Therefore, the second electrode layer 143 is disposed between the insulating layer 142 and the another insulating layer 145, and the second electrode layer 143, the data line D and the first electrode layer 141 won't be short-circuited to each other. The material of the insulating layer 142 and another insulating layer 145 can include SiOx, SiNx or other insulating materials for example, but this invention is not limited thereto. Moreover, the first electrode layer 141 and the second electrode layer 143 are a transparent conductive layer, and the material thereof is, for example but not limited to, indium-tin oxide (ITO) or indium-zinc oxide (IZO). In this embodiment, the first electrode layer 141 connects electrically to the data line D for being a pixel electrode, and the second electrode layer 143 is a common electrode. However, in other embodiments, the first electrode layer 141 can be a common electrode while the second electrode layer 143 is a pixel electrode.

The display panel 1 can further include a black matrix BM and a color filter layer (not shown). The black matrix BM is disposed on the first substrate 11 or second substrate 12 and corresponding to the data lines D. The black matrix BM is made by opaque material, such as metal (e.g. Cr, chromium oxide, or Cr—O—N compound) or resin. In this embodiment, the black matrix BM is disposed on the second substrate 12 and faces the first substrate 11 to over the data line D along the third direction Z. Accordingly, the black matrix BM covers the data lines D in a top view of the display panel 1. The color filter layer (not shown) is disposed on the second substrate 12 and black matrix BM, or the color filter layer is disposed on the first substrate 11 in another embodiment. Since the black matrix BM is opaque, a corresponding opaque area can be formed on the second substrate 12 and a transparent area can be thus defined. The black matrix BM includes a plurality of light-blocking segments disposed between two adjacent color filter portions of the color filter layer. In this embodiment, the black matrix BM and the color filter layer are both disposed on the second substrate 12. In other embodiments, however, the black matrix BM or the color filter layer can be disposed on the first substrate 11 for making a BOA (BM on array) substrate or a COA (color filter on array) substrate. To be noted, the above-mentioned structure of the substrate is just for the illustrative purpose but not for limiting the scope of the invention. Moreover, the display panel 1 can further include a protection layer (e.g. an over-coating layer, not shown), which can cover the black matrix BM and the color filter layer. The protection layer can include photoresist material, resin material or inorganic material (e.g. SiOx/SiNx). The protection layer protects the black matrix BM and the color filter layer from being damaged by the subsequent processes, and forms a smooth surface on the second substrate 12.

As shown in FIG. 1B, the first electrode layer 141 includes an auxiliary electrode portion 1411 and a driving electrodes portion 1412 connecting to the auxiliary electrode portion 1411. The auxiliary electrode portion 1411 has at least a through hole O, and the first electrode layer 141 is electrically connected to a thin film transistor (not shown) of the pixel P through the through hole O. Herein, the thin film transistor is a driving transistor of the pixel P, and when the thin film transistor is turned on, the gray-level voltage of the pixel P will be transmitted to the first electrode layer 141 through the source and drain of the thin film transistor. The area of the auxiliary electrode portion 1411 is denoted by A1.

The driving electrode portion 1412 includes a plurality of strip electrodes which are spaced from each other along the first direction X and connect to the auxiliary electrode portion 1411. In this embodiment, as shown in FIG. 1B, there are three strip electrodes (denoted by S1, S2, S3) and the auxiliary electrode portion 1411 is connected to one end of each of the strip electrodes S1, S2, S3. The strip electrodes S1, S2, S3 space out each other from an interval and are arranged parallelly along the first direction X. However, in other embodiments, there can be different number of the strip electrodes, such as two, four or others. Besides, the driving electrode portion 1412 of this embodiment further includes a connecting electrode S4, which is disposed on the side away from the auxiliary electrode portion 1411 and connected to another end of each of the strip electrodes S1, S2, S3. Herein, the area of the driving electrode portion 1412 is denoted by A2.

FIG. 1C is a schematic diagram of the light-emitting zone of the pixel P when a light passes through the pixel P in an embodiment of the invention, FIG. 1D is a schematic diagram of a brightness distribution curve of the light-emitting zone of the pixel P along the first direction X, and FIG. 1E is a schematic diagram of a brightness distribution curve of the light-emitting zone of the pixel P along the second direction Y.

As shown in FIG. 1C, when light passes through the pixel P, the pixel P will have a light-emitting zone (the area of the light-emitting zone relates to the pattern design of the first electrode layer and driving voltage). When the light passes through the pixel P in the biggest gray level (usually 255 gray level), as shown in FIG. 1D, the light-emitting zone has a first brightness curve C1 (the brightness has been normalized) along the first direction X. Moreover, as shown in FIG. 1E, when the light passes through the pixel P, the light-emitting zone has a second brightness curve C2 (the brightness also has been normalized) along the second direction Y. Therefore, in this embodiment, the area B of the light-emitting zone can be defined as the full width at half maximum (FWHM) Ax of the first brightness curve C1 along the first direction X (FWHM is the width of the x coordinate at the half brightness of the brightness distribution curve) multiplied by the FWHM Ay of the second brightness curve C2 along the second direction Y (generally in design, Ay≈Ax, and the first direction X is perpendicular to the second direction Y).

Accordingly, when the scan lines receive the scan signals, the corresponding thin film transistors of the pixels P are turned on and the corresponding data signals can be transmitted to the corresponding pixel electrodes through the data lines D and the display panel 1 can thus display images. In this embodiment, the gray-level voltages can be transmitted to the first electrode layers 141 (pixel electrodes) of the pixels P through the data lines D, so that an electric field is formed between the first electrode layer 141 and the second electrode layer 143 to drive the liquid crystal molecules of the liquid crystal layer 13 to rotate on the plane of the first and second directions X and Y, and therefore the light can be modulated and the display panel 1 can display images accordingly.

As shown in FIG. 1B, for the design of a pixel P, when the driving electrode portion 1412 has a larger area A2, the area B of the light-emitting zone of the pixel P will be increased (because the two areas are in proportion to each other) and the transmittance of the pixel P will also be increased. However, when the size of the pixel P and the design of the thin film transistor are fixed, the area A2 of the driving electrode portion 1412 is also limited. In other words, the area A2 of the driving electrode portion 1412 can be increased in order to increase the transmittance of the display panel 1, but the area A1 of the auxiliary electrode portion 1411 would be decreased. However, the smaller auxiliary electrode portion 1411 will affect not only the disposition alignment of the through hole O but also the electric property of the pixel P. For example, the smaller auxiliary electrode portion 1411 will lessen the capacitance of the pixel P (including the storage capacitance and the liquid crystal capacitance) to influence the charging time and driving voltage of the liquid crystal molecules. On the other side, although the larger auxiliary electrode portion 1411 will increase the capacitance of the pixel P so as to increase the charging time (this is a disadvantage for a high-ppi display panel), the current leakage of the thin film transistor of the pixel P would reduce and therefore the gray-level voltage of the pixel can more approach the actual charging voltage. Accordingly, the ratio of the area A1 of the auxiliary electrode portion 1411 of the pixel P to the area A2 (or the area B of the light-emitting zone) of the driving electrode portion 1412 needs to be carefully considered to satisfy the requirements of both the electric property and optical property.

In general, the actual charging voltage of the pixel is about equal to the gray-level voltage inputting from the data line D minus the charging error Ve and minus the capacitive coupling voltage (can be called the feed through voltage) V_{FT} (i.e. the actual charging voltage=gray-level voltage−Ve−V_{FT}). Accordingly, in order to make the actual charging voltage of the pixel P approach the gray-level voltage to obtain a better display quality, the sum of the charging error Ve and the capacitive coupling voltage V_{FT} will be the smaller the better. The equations of the charging error Ve and capacitive coupling voltage V_{FT} can be as follows:

$$\begin{matrix}Ve = {V}_{0} - {V}_{0} ( 1 - {e}^{( - t / RC )} ) & ( equation 1 ) \\ {V}_{FT} = \frac{{C}_{gd}}{C} ( {V}_{gH} - {V}_{gL} ) & ( equation 2 )\end{matrix}$$

C denotes the total capacitance of the pixel P (i.e. the sum of the storage capacitance, the parasitic capacitance and the liquid crystal capacitance), C_{gd} denotes the parasitic capacitance between the gate and drain of the thin film transistor, R denotes the resistance of the thin film transistor, and V_{gH} and V_{gL} denote the control voltage to the thin film transistor.

Then, by using the direct proportion relationship between the capacitance and the electrode area, the charging error Ve and the capacitive coupling voltage V_{FT} can be derived as follows:

$$\begin{matrix}Ve = {V}_{0} - {V}_{0} ( 1 - {e}^{( - t / RC )} ) \\ = {V}_{0} \times {e}^{( - t / RC )} \\ = {V}_{0} \times {e}^{( - t / R ( ɛ \frac{A 1 + A 2}{d} ) )} \\ = {V}_{0} \times {e}^{( - t / [ \frac{R ɛ A 2}{d} ] ( \frac{A 1}{A 2} + 1 ) )} \\ = {V}_{0} \times {e}^{( [ \frac{- td}{R ɛ A 2} ( \frac{A 1}{A 2} ) ] \frac{td}{R ɛ A 2} )}\end{matrix}$$

Because the area A2 of the driving electrode portion 1412 and the area B of the light-emitting zone will be designed approximately with a direct proportion, A2 is set as (B/a), and “a” is about 0.76 in an embodiment. Therefore, the equation can be obtained as follows:

$$Ve = {V}_{0} \times {e}^{( [ \frac{- {tda}^{2}}{R ɛ B} ( \frac{A 1}{B} ) ] - \frac{tda}{R ɛ B} ) )}$$

Besides,

$$\begin{matrix}{V}_{FT} = \frac{{C}_{gd}}{C} ( {V}_{gH} - {V}_{gL} ) \\ = \frac{d \times {C}_{gd} ( {V}_{gH} - {V}_{gL} )}{( ɛ \times A 2 ( \frac{A 1}{A 2} + 1 )} \\ = \frac{d \times {C}_{gd} ( {V}_{gH} - {V}_{gL} )}{( ɛ \times A 2 ( \frac{A 1}{A 2} ) + ɛ \times A 2 )} \\ = \frac{{C}_{gd}}{( ɛ \frac{A 1 + A 2}{d} )} ( {V}_{gH} - {V}_{gL} ) \\ = \frac{d \times {C}_{gd}}{ɛ ( A 1 + A 2 )} ( {V}_{gH} - {V}_{gL} ) \\ = \frac{d \times {C}_{gd} ( {V}_{gH} - {V}_{gL} )}{( ɛ \times B ( \frac{A 1}{B} ) + ɛ \times \frac{B}{a} )}\end{matrix}$$

Next, the sum of Ve and V_{FT} can be represented by a function manner as follows:

$$f ( \frac{A 1}{B} ) = Ve + {V}_{FT} = {V}_{0} \times {e}^{( [ \frac{- {tda}^{2}}{R ɛ B} ( \frac{A 1}{B} ) ] - \frac{tda}{R ɛ B} ) )} + \frac{d \times {C}_{gd} ( {V}_{gH} - {V}_{gL} )}{( ɛ \times B ( \frac{A 1}{B} ) + ɛ \times \frac{B}{a} )}$$

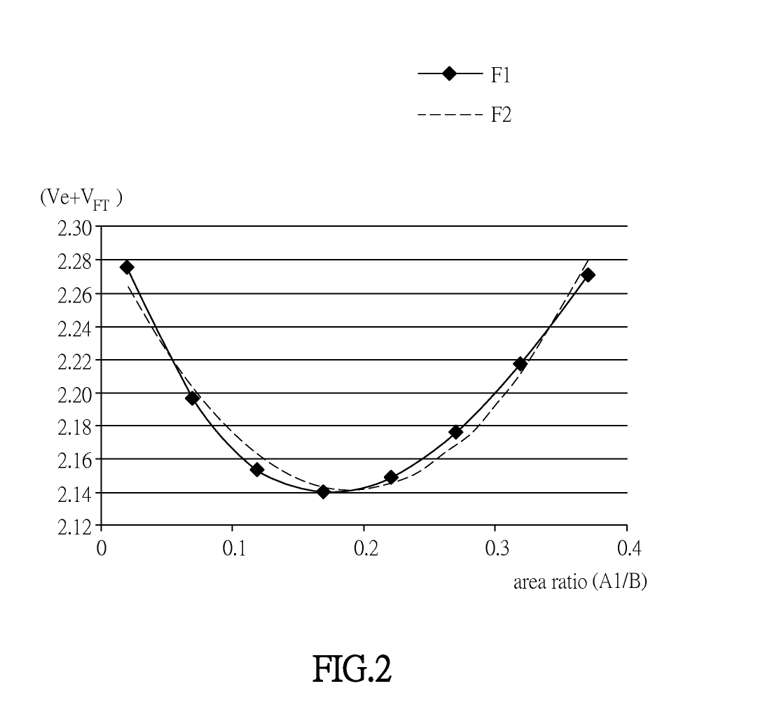

It is better when the function f has the minimum value, it means the actual charging voltage of the pixel P approaches the gray-level voltage. However the differentiation of the function f is really complicated, it is not directly solved by differentiation in this invention but solved with a numerical solution. In the numerical solution, some data (C_{gd}, R, C, V_{gH}, C_{gL}) of the pixel P are substituted into the equations 1, 2. Accordingly, the data of different pixel embodiment can result in the different values of (Ve+V_{FT}) in FIG. 2, and the curve F1 formed by the actual data can be thus obtained. Then, the trend curve F2 of (Ve+V_{FT}) can be obtained by simulating the curve F1 with a mathematical method. So, the equation of the curve F2 can be obtained as follows:

$$y = f ( \frac{A 1}{B} ) = 4.2792 {x}^{2} - 1.628 x + 2.296$$

For obtaining the minimum of (Ve+V_{FT}), the above equation is differentiated to derive the extreme value as follows:

$${y}^{′} = {f}^{′} ( \frac{A 1}{B} ) = 8.558 x - 1.628 = 0$$

$$\frac{A 1}{B} = 0.19$$

According to the results above-mentioned, when the ratio of the area A1 of the auxiliary electrode portion 1411 to the area B of the light-emitting zone is 0.19, the sum of the charging error Ve and the capacitive coupling voltage V_{FT} is the smallest, so that the bias between the actual charging voltage of the pixel electrode and the gray-level voltage is minimized. Besides, the charging efficiency can improve so that the transmittance of the pixel P can be maximized. Therefore, the display panel 1 can be configured with a higher transmittance to enhance the product competitiveness.

However, in consideration of the variation of the process, the display panel 1 can have a better transmittance in this embodiment when A1 and B satisfy the following inequality: 0.11×B≦A1≦0.27×B, wherein A1 and B have the unit of μm². Favorably, the display panel 1 can have a much better transmittance in this embodiment when A1 and B satisfy the following inequality: 0.13×B≦A1≦0.25×B.

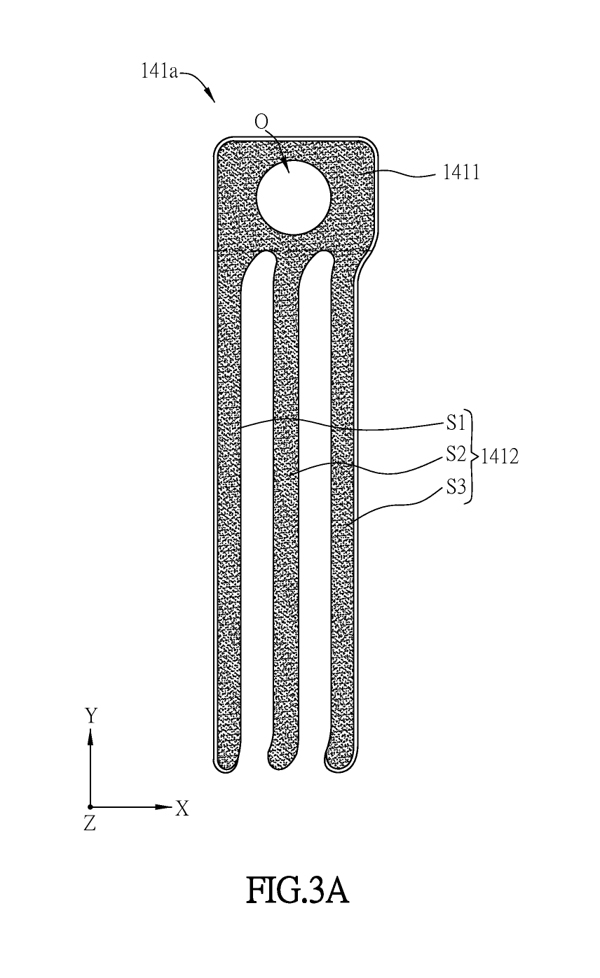

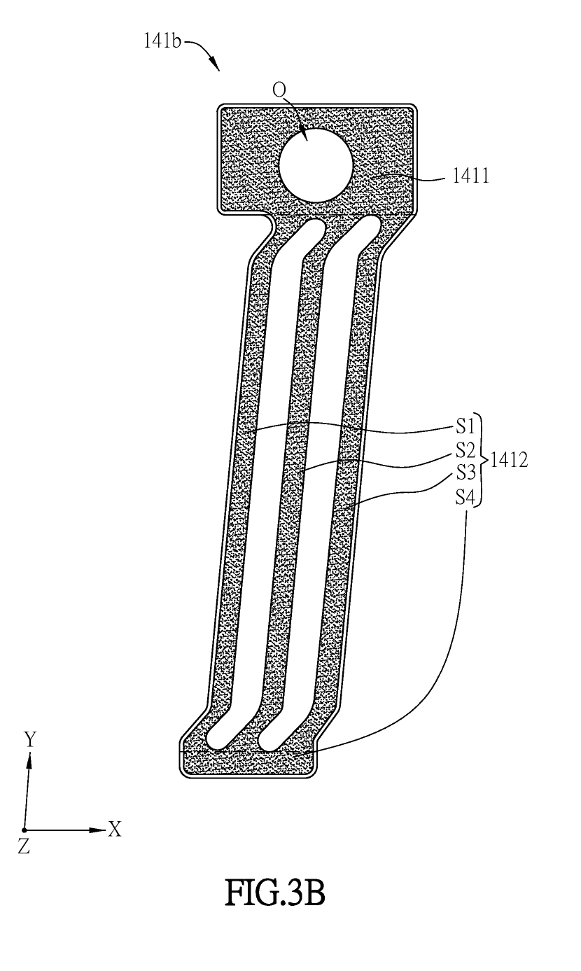

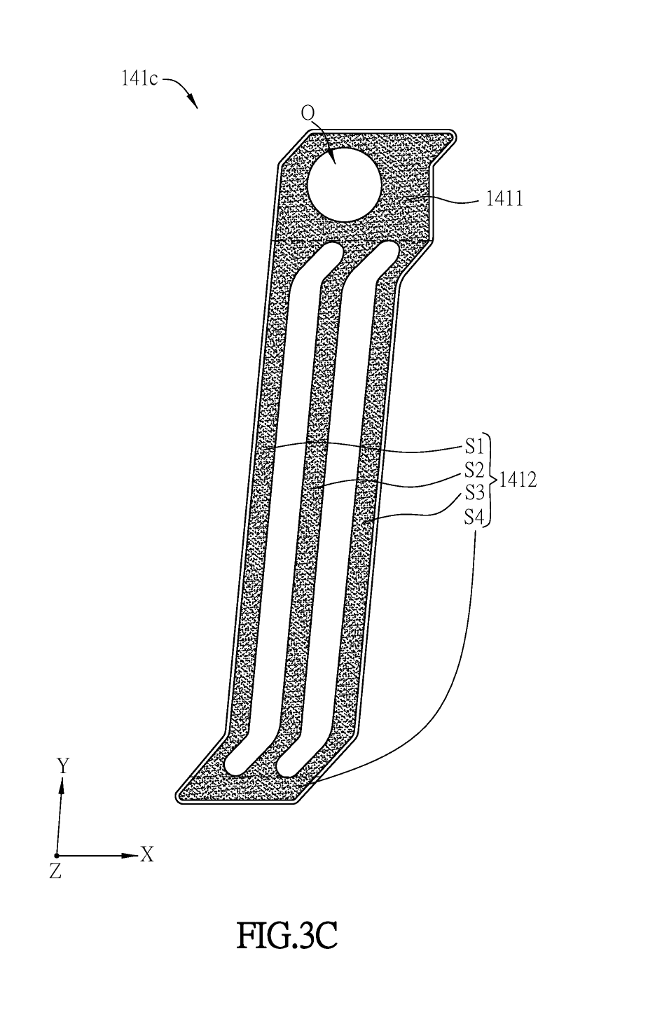

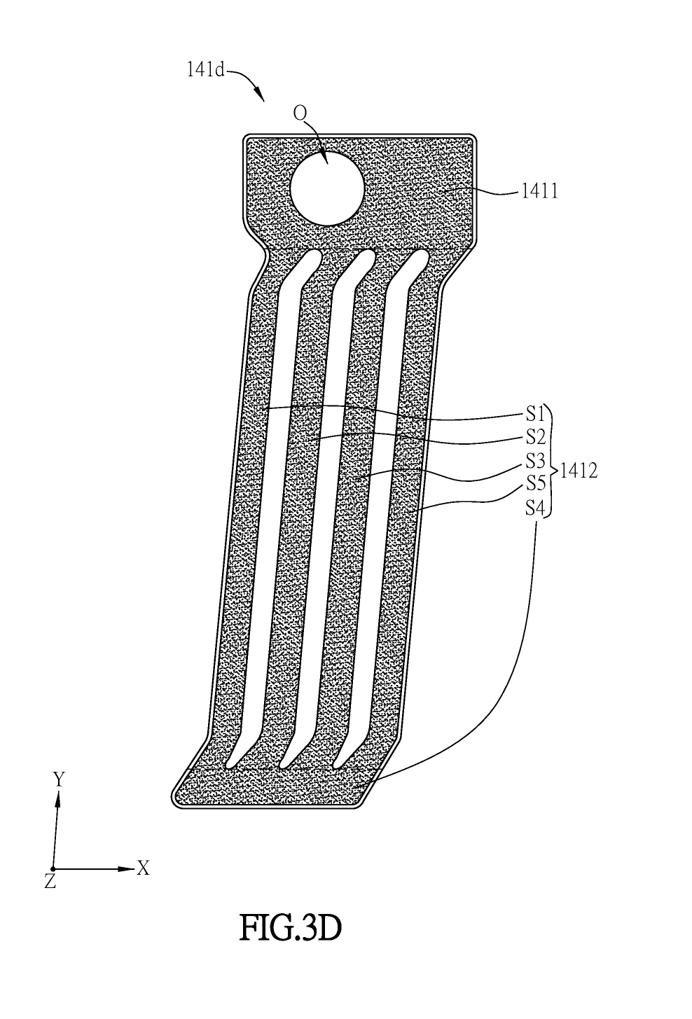

FIGS. 3A to 3D are schematic diagrams of the first electrode layers 141a˜141d of different embodiments of the invention. To be noted, the patterns of the first electrode layers 141a˜141d in FIGS. 3A to 3D are just for the illustrative purpose but not for limiting the scope of the invention.

As shown in FIG. 3A, the main difference between the first electrode layer 141a and the first electrode layer 141 in FIG. 1B is that the first electrode layer 141a just has three strip electrodes S1, S2, S3 but doesn't have the connecting electrode S4.

As shown in FIG. 3B, the main difference between the first electrode layer 141b and the first electrode layer 141 in FIG. 1B is that the second direction Y in the first electrode layer 141b is still substantially parallel to the extension direction of the data line D but the first direction X and the second direction Y have an acute angle instead of a right angle, so that the pixel is approximately shaped like a parallelogram. Moreover, each of the strip electrodes S1, S2, S3 of the first electrode layer 141b has two turns. Besides, the joint of the auxiliary electrode portion 1411 and the driving electrode portion 1412 is slightly different from the embodiment of FIG. 1B.

As shown in FIG. 3C, the main difference between the first electrode layer 141c and the first electrode layer 141b in FIG. 3B is that the strip electrode S1 of the first electrode layer 141c just has one turn but each of the strip electrodes S2, S3 of the first electrode layer 141c has two turns. Besides, the joint of the auxiliary electrode portion 1411 and the driving electrode portion 1412 and the shape of the auxiliary electrode portion 1411 are slightly different from the embodiment of FIG. 3B.

As shown in FIG. 3D, the main difference between the first electrode layer 141d and the first electrode layer 141b in FIG. 3B is that the first electrode layer 141d has four strip electrodes S1, S2, S3, S4, so that the area of the first electrode layer 141d is greater than that of the first electrode layer 141b.

Other technical features of the first electrode layers 141a-141d can be comprehended by referring to the same elements of the first electrode layer 141, and therefore their descriptions are omitted here for conciseness.

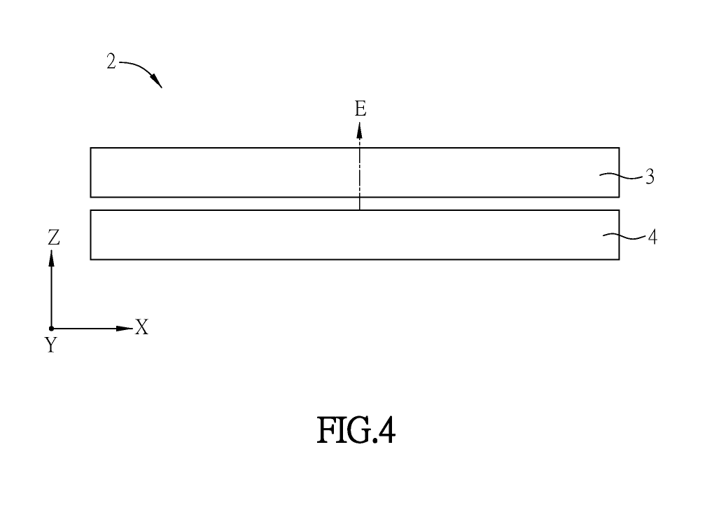

FIG. 4 is a schematic diagram of a display device 2 of an embodiment of the invention.

The display device 2 includes a display panel 3 and a backlight module 4 disposed opposite the display panel 3. The display panel 3 can be the above-mentioned display panel 1, and the first electrode layer of the pixel of the display panel 1 can be the above-mentioned first electrode layer 141, 141a, 141b, 141c or 141d or their variations. The related structure and details can be comprehended by referring to the above embodiments and therefore are omitted here for conciseness. When the backlight module 4 emits the light passing through the display panel 3, the pixels of the display panel 3 can display colors forming images.

Summarily, in the display panel and display device of the invention, the driving electrode portion of the first electrode layer of the pixel has a plurality of strip electrodes spaced from each other along a first direction, and the area of the auxiliary electrode portion is denoted by A1. When a light passes through the pixel, the area of the light-emitting zone of the pixel is denoted by B. A1 and B satisfy the following equation: 0.11×B≦A1≦0.27×B. Thereby, when the area A1 of the auxiliary electrode portion and the area B of the light-emitting zone of the pixel satisfy the above equation, the display panel and device can meet the requirements of both the electric property and the optics, so that the transmittance of the pixel is maximized. Therefore, the display panel and device of the invention can have a higher transmittance and the product competitiveness can be enhanced.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display panel, comprising:
a first substrate;
a second substrate disposed opposite the first substrate; and
a pixel array disposed between the first substrate and the second substrate and including at least an pixel including a first electrode layer, wherein the first electrode layer has an auxiliary electrode portion and a driving electrode portion connecting to the auxiliary electrode portion, the driving electrode portion has a plurality of strip electrodes spaced from each other and arranged along a first direction, the area of the auxiliary electrode portion is denoted by A1, when a light passes through the pixel, the pixel has a light-emitting zone having an area denoted by B, A1 and B satisfy the following equation: 0.11×B≦A1≦0.27×B, and the units of A1 and B are the same.

2. The display panel as recited in claim 1, wherein A1 and B further satisfy the following inequality: 0.13×B≦A1≦0.25×B.

3. The display panel as recited in claim 1, wherein the light-emitting zone has a first brightness curve along the first direction, and has a second brightness curve along the second direction, the area B of the light-emitting zone is the full width at half maximum (FWHM) of the first brightness curve along the first direction multiplied by the FWHM of the second brightness curve along the second direction, and the first direction is perpendicular to the second direction.

4. The display panel as recited in claim 1, wherein the auxiliary electrode portion has at least a through hole, and the first electrode layer is electrically connected to a thin film transistor by the through hole.

5. The display panel as recited in claim 1, wherein the driving electrode portion further includes a connecting electrode, which is disposed away from the auxiliary electrode portion and connected to the strip electrodes.

6. A display device, comprising:
a display panel including a first substrate, a second substrate and a pixel array, wherein the second substrate is disposed opposite the first substrate, the pixel array is disposed between the first substrate and the second substrate and includes at least an pixel including a first electrode layer, the first electrode layer has an auxiliary electrode portion and a driving electrode portion connecting to the auxiliary electrode portion, the driving electrode portion has a plurality of strip electrodes spaced from each other and arranged along a first direction, the area of the auxiliary electrode portion is denoted by A1, when a light passes through the pixel, the pixel has a light-emitting zone having an area denoted by B, A1 and B satisfy the following equation: 0.11×B≦A1≦0.27×B, and the units of A1 and B are the same.

7. The display device as recited in claim 6, wherein A1 and B further satisfy the following inequality: 0.13×B≦A1≦0.25×B.

8. The display device as recited in claim 6, wherein the light-emitting zone has a first brightness curve along the first direction, and has a second brightness curve along the second direction, the area B of the light-emitting zone is the full width at half maximum (FWHM) of the first brightness curve along the first direction multiplied by the FWHM of the second brightness curve along the second direction, and the first direction is perpendicular to the second direction.

9. The display device as recited in claim 6, wherein the auxiliary electrode portion has at least a through hole, and the first electrode layer is electrically connected to a thin film transistor by the through hole.

10. The display device as recited in claim 6, wherein the driving electrode portion further includes a connecting electrode, which is disposed away from the auxiliary electrode portion and connected to the strip electrodes.
